(19) United States
(12) Patent Application Publication
(10) Pub. No.: US 2025/0087621 A1
(43) Pub. Date: Mar. 13, 2025

(54) INTERPOSER STRUCTURE AND PACKAGE STRUCTURE

(71) Applicant: Advanced Semiconductor Engineering, Inc., Kaohsiung (TW)

(72) Inventors: Chih-Jing HSU, Kaohsiung (TW); Hsu-Nan FANG, Kaohsiung (TW)

(73) Assignee: Advanced Semiconductor Engineering, Inc., Kaohsiung (TW)

(21) Appl. No.: 18/244,205

(22) Filed: Sep. 8, 2023

(51) Int. Cl. H01L 23/00; H01L 23/31; H01L 23/498; H01L 25/065

(52) U.S. Cl. CPC H01L 24/48; H01L 23/3107; H01L 23/49822; H01L 23/49838; H01L 24/08; H01L 25/0655; H01L 2224/08137; H01L 2224/08146; H01L 2224/48095; H01L 2224/48227; H01L 2924/18161; H01L 2924/182

(57) ABSTRACT

An interposer structure and a package structure are provided. The interposer structure includes a conductive portion, a dielectric layer, a plurality of first wires, and a plurality of second wires. The conductive portion has a first surface and a second surface opposite to the first surface. The dielectric layer encapsulates the conductive portion and exposes the first surface and the second surface. The first wires are formed on the first surface. The second wires are disposed over the second surface.

### BACKGROUND

### 1. Technical Field

The present disclosure relates generally to an interposer structure and a package structure.

### 2. Description of the Related Art

Devices or semiconductor wafers may be bonded to each other through various hybrid bonding techniques. Currently, the devices and/or the semiconductor wafers are bonded after chemical mechanical polishing (CMP) processes are performed on the devices and/or the semiconductor wafers. The CMP processes may cause the bonding surfaces on the devices and/or the semiconductor wafers to be uneven, resulting in decreased bonding strength and thus deteriorated device reliability.

### SUMMARY

In one or more arrangements, an interposer structure includes a conductive portion, a dielectric layer, a plurality of first wires, and a plurality of second wires. The conductive portion has a first surface and a second surface opposite to the first surface. The dielectric layer encapsulates the conductive portion and exposes the first surface and the second surface. The first wires are formed on the first surface. The second wires are disposed over the second surface.

In one or more arrangements, a package structure includes a first substrate, a second substrate, and an interposer. The second substrate is over the first substrate. The interposer is between the first substrate and the second substrate. The interposer includes a network portion and a dielectric layer. The network portion electrically connects the first substrate and the second substrate. The dielectric layer at least partially encapsulates the network portion and bonds the first substrate and the second substrate.

In one or more arrangements, a package structure includes a first substrate, a second substrate, and an interposer. The second substrate is over the first substrate. The interposer is between the first substrate and the second substrate. The interposer includes a conductive structure electrically connecting the first substrate and the second substrate. The conductive structure includes an upper portion, a lower portion, and a seed layer between the upper portion and the lower portion, a first void is formed within the upper portion, and a second void is formed within the lower portion.

### BRIEF DESCRIPTION OF THE DRAWINGS

Aspects of the present disclosure are better understood from the following detailed description when read with the accompanying drawings. It is noted that various features may not be drawn to scale, and the dimensions of the various features may be arbitrarily increased or reduced for clarity of discussion.

FIG. 1 is a cross-section of an interposer structure in accordance with some arrangements of the present disclosure.

FIG. 1A is a cross-section of a package structure in accordance with some arrangements of the present disclosure.

FIG. 1B is a cross-section of a portion of a package structure in accordance with some arrangements of the present disclosure.

FIG. 1C is a cross-section of a portion of a package structure in accordance with some arrangements of the present disclosure.

FIG. 1D is a cross-section of a portion of a package structure in accordance with some arrangements of the present disclosure.

FIG. 2A is a cross-section of a package structure in accordance with some arrangements of the present disclosure.

FIG. 2B is a cross-section of a package structure in accordance with some arrangements of the present disclosure.

FIG. 2C is a cross-section of a package structure in accordance with some arrangements of the present disclosure.

FIG. 2D is a cross-section of a package structure in accordance with some arrangements of the present disclosure.

FIG. 3A, FIG. 3B, FIG. 3C, FIG. 3D, FIG. 3E, FIG. 3F, FIG. 3G, FIG. 3H, FIG. 3I, FIG. 3J, FIG. 3K, and FIG. 3L illustrate various stages of an exemplary method for manufacturing a package structure in accordance with some embodiments of the present disclosure.

FIG. 4A, FIG. 4B, FIG. 4C, FIG. 4D, and FIG. 4E illustrate various stages of an exemplary method for manufacturing a package structure in accordance with some embodiments of the present disclosure.

Common reference numerals are used throughout the drawings and the detailed description to indicate the same or similar elements. The present disclosure will be more apparent from the following detailed description taken in conjunction with the accompanying drawings.

### DETAILED DESCRIPTION

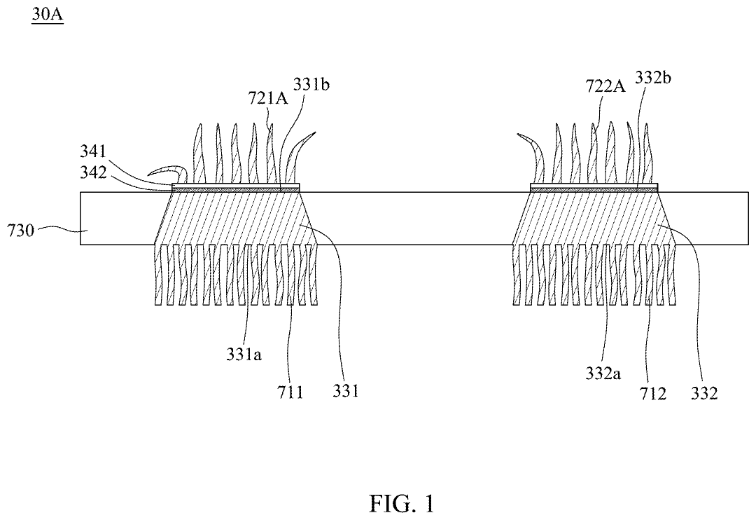

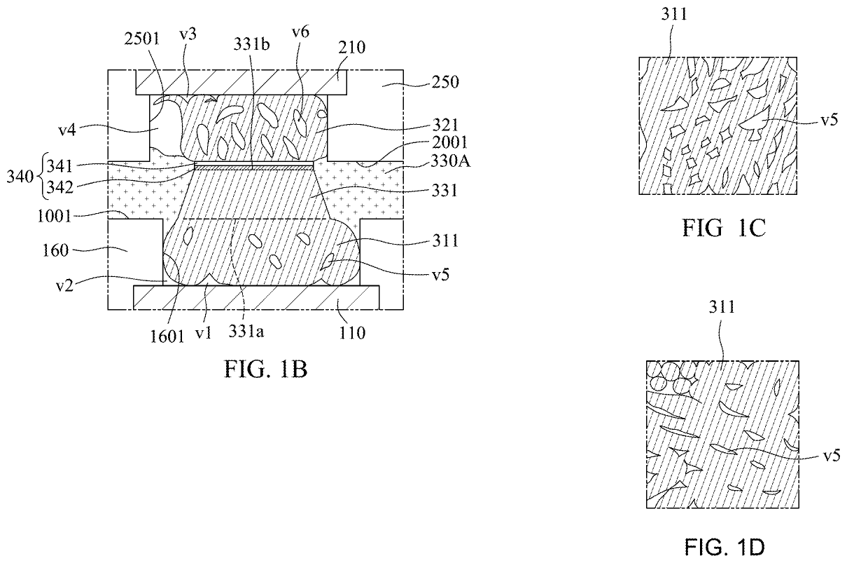

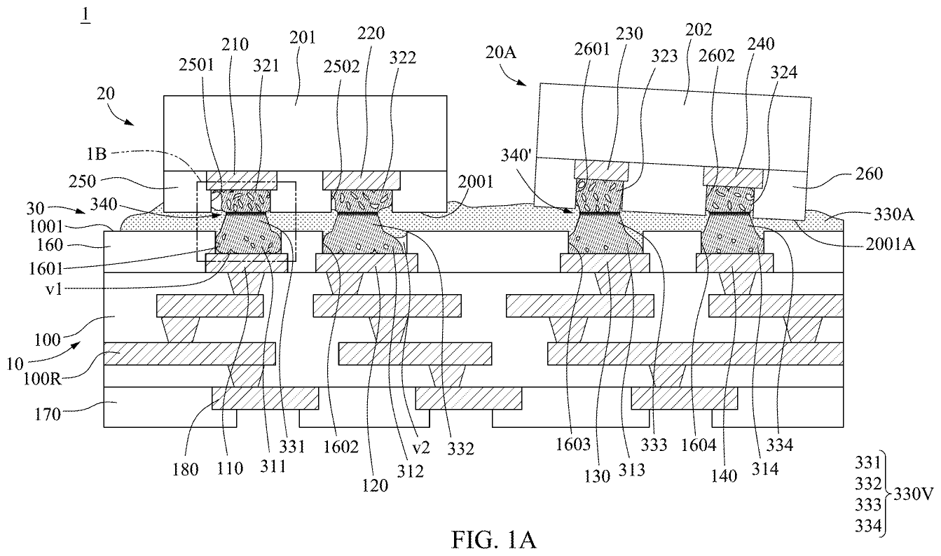

FIG. 1 is a cross-section of an interposer structure 30A in accordance with some arrangements of the present disclosure. The interposer structure 30A may include one or more conductive portions (e.g., conductive vias 331 and 332), a dielectric layer (e.g., a patterned dielectric layer 730), wires (e.g., wires 711, 712, 721A, and 722A), and conductive layers (e.g., seed layers 341 and 342).

The conductive via 331 may have a surface 331a and a surface 331b opposite to the surface 331a, and the conductive via 332 may have a surface 332a and a surface 332b opposite to the surface 332a. The conductive vias 331 and 332 are substantially free of voids (e.g., pores, air voids, air gaps, or the like). In some arrangements, the conductive vias 331 and 332 are spaced apart from each other by the patterned dielectric layer 730A. In some arrangements, the conductive vias 331 and 332 taper from the surfaces 331a and the 332a toward the surfaces 331b and 332b. The conductive vias 331 and 332 may independently include a conductive material such as a metal or metal alloy. Examples include gold (Au), silver (Ag), aluminum (Al), copper (Cu), or an alloy thereof.

In some arrangements, the patterned dielectric layer 730 may encapsulate the conductive vias 331 and 332 and expose the surfaces 331a, 331b, 332a, and 332b. In some arrangements, the patterned dielectric layer 730 has openings (or through holes), and the conductive vias 331 and 332 are disposed or formed in the openings. The patterned dielectric layer 730 may include polyimide (PI).

In some arrangements, the wires 711 are formed on the surface 331a, and the wires 712 are formed on the surface 332a. In some arrangements, the wires 711 and the conductive via 331 are formed integrally as a single piece element or a monolithic structure. In some arrangements, the wires 712 and the conductive via 332 are formed integrally as a single piece element or a monolithic structure. In some arrangements, there is no seed layer between the wires 711 and the conductive via 331. In some arrangements, the conductive via 331 and the wires 711 are continuously formed. In some arrangements, the conductive via 331 and the wires 711 are formed continuously in the same plating process. In some arrangements, the conductive via 331 and the wires 711 have a substantially uniform grain size or a substantially uniform grain size distribution. In some arrangements, the grain size of the conductive via 331 is substantially the same as or close to the grain size of the wires 711. In some arrangements, there is no seed layer between the wires 712 and the conductive via 332. In some arrangements, the conductive via 332 and the wires 712 are continuously formed. In some arrangements, the conductive via 332 and the wires 712 are formed continuously in the same plating process. In some arrangements, the conductive via 332 and the wires 712 have a substantially uniform grain size or a substantially uniform grain size distribution. In some arrangements, the grain size of the conductive via 332 is substantially the same as or close to the grain size of the wires 712.

In some arrangements, the wires 721A are disposed on or over the surface 331b, and the wires 722A are disposed on or over the surface 332b. In some arrangements, the wires 721A and 722A have tapered profiles. In some arrangements, a distribution density of the wires 721A and 722A is lower than a distribution density of the wires 711 and 712. In some arrangements, a width of the wires 721A and 722A is greater than a width of the wires 711 and 712. In some arrangements, in a cross-section view, a pitch of the wires 711 is different from (e.g., less than) a pitch of the wires 721A. In some arrangements, a pitch of the wires 712 is different from (e.g., less than) a pitch of the wires 722A. In some arrangements, a portion of the wires 711 is not vertically overlapped by the wires 721A. In some arrangements, a portion of the wires 712 is not vertically overlapped by the wires 722A.

In some arrangements, the seed layers 341 and 342 are between the wires 721A and the conductive via 331. In some arrangements, the seed layers 341 and 342 are between the wires 722A and the conductive via 332. In some arrangements, in a cross-section view, the conductive vias 331 and 332 taper toward the seed layers 341 and 342. The seed layers 341 and 342 may independently include, for example, titanium (Ti), copper (Cu), nickel (Ni), another metal, an alloy (such as a titanium-tungsten alloy (TiW)), or a combination thereof. In some arrangements, the seed layer 342 is made of or include Cu, and the seed layer 341 is made of or includes Ti.

FIG. 1A is a cross-section of a package structure 1 in accordance with some arrangements of the present disclosure. The package structure 1 may include substrates 10, 20 and 20A and an interposer (e.g., a patterned interposer 30.)

The substrates 10, 20, and 20A may independently include, for example, a printed circuit board, such as a paper-based copper foil laminate, a composite copper foil laminate, or a polymer-impregnated glass-fiber-based copper foil laminate. The substrates 10, 20, and 20A may independently include an interconnection structure, which may include such as a plurality of conductive traces and/or a plurality of conductive vias. The interconnection structure may include a redistribution layer (RDL) and/or a grounding element. In some arrangements, the substrates 10, 20, and 20A may independently include an organic substrate or a leadframe. In some arrangements, the substrates 10, 20, and 20A may independently include a ceramic material or a metal plate. In some arrangements, the substrates 10, 20, and 20A may independently include a two-layer substrate which includes a core layer and a conductive material and/or structure disposed on an upper surface and a bottom surface of the substrate. The substrates 10, 20, and 20A may independently include a semiconductor wafer or an electronic component. The electronic component may be a chip or a die including a semiconductor substrate, one or more integrated circuit devices and one or more overlying interconnection structures therein. The integrated circuit devices may include active devices such as transistors and/or passive devices such resistors, capacitors, inductors, or a combination thereof. In some arrangements, the substrates 10, 20, and 20A may independently include one or more conductive elements, surfaces, contacts, or pads.

In some arrangements, the substrate 10 includes a dielectric structure 100, a wiring structure 100R in the dielectric structure 100, dielectric layers 160 and 170 on opposite surfaces of the dielectric structure 100, and conductive pads 110 to 140 and 180 respectively on opposite surfaces of the dielectric structure 100. In some arrangements, the wiring structure 100R includes a plurality of wiring layers (or conductive layers) and a plurality of conductive vias connecting the wiring layers, and the dielectric structure 100 may include a plurality of dielectric layers (not shown) disposed between the wiring layers of the wiring structure 100R. In some arrangements, the dielectric layer 160 defines one or more openings (e.g., recesses 1601, 1602, 1603, and 1604) that expose one or more portions of an upper surface of the dielectric structure 100. In some arrangements, the conductive pads 110, 120, 130, and 140 are disposed on the exposed upper surface of the dielectric structure 100 and electrically connected to the wiring structure 100R. In some arrangements, the conductive pads 180 are disposed on a bottom surface of the dielectric structure 100 and electrically connected to the conductive pads 110 to 140 through the wiring structure 100R, and the dielectric layer 170 covers the bottom surface of the dielectric structure 100 and portions of the conductive pads 180. In some arrangements, the dielectric layer 170 defines a plurality of openings (or recesses), and portions of the conductive pads 180 are exposed by the openings of the dielectric layer 170.

In some arrangements, each of the recesses 1601, 1602, 1603, and 1604 exposes at least a portion of each of the conductive pads 110, 120, 130, and 140, respectively. In some arrangements, each of the conductive pads 110, 120, 130, and 140 is respectively exposed by each of the recesses 1601, 1602, 1603, and 1604. The substrate 10 may be referred to as or include a wiring structure, a circuit structure, a conductive structure, or a conductive carrier.

The substrate 20 may be disposed over the substrate 10. In some arrangements, the substrate 20 is electrically connected to the substrate 10. In some arrangements, the substrate 20 includes a substrate layer 201 (e.g., a semiconductor layer, for example, a silicon-based layer), a dielectric layer 250 (also referred to as “a passivation layer”) on a bottom surface of the substrate layer 201, and conductive pads 210 and 220 on the bottom surface of the substrate layer 201. In some arrangements, the dielectric layer 250 has one or more openings (e.g., recesses 2501 and 2502) exposing at least a portion of the conductive pads 210 and 220. The substrate 20 may include a semiconductor wafer or an electronic component. The electronic component may be or include a passive die or an active die such as an application specific integrated circuit (ASIC) or any other type of active dies.

In some arrangements, the substrate 20A is electrically connected to the substrate 10. In some arrangements, the substrate 20A includes a substrate layer 202 (e.g., a semiconductor layer, for example, a silicon-based layer), a dielectric layer 260 (also referred to as “a passivation layer”) on a bottom surface of the substrate layer 202, and conductive pads 230 and 240 on the bottom surface of the substrate layer 202. In some arrangements, the dielectric layer 260 has one or more openings (e.g., recesses 2601 and 2602) exposing at least a portion of the conductive pads 230 and 240. In some arrangements, the substrate 20A (or a bottom surface 2001A of the substrate 20A) is non-parallel to the substrate 10. The substrate 20A may include a semiconductor wafer or an electronic component. The electronic component may be or include a passive die or an active die such as an ASIC or any other type of active dies.

In some arrangements, the patterned interposer 30 is disposed between the substrate 10 and the substrates 20 and 20A. In some arrangements, the patterned interposer 30 electrically connects the substrate 10 to the substrates 20 and 20A. In some arrangements, the patterned interposer 30 includes an insulating layer 330A (also referred to as “an insulating buffer layer,” “an insulating portion,” or “a dielectric layer”), a patterned via layer 330V, conductive portions (e.g., conductive portions 311, 312, 313, 314, 321, 322, 323, and 324), and seed layers (e.g., seed layer structures 340 and 340′). The conductive portions may be referred to as or construct one or more network portions that electrically connect the substrate 10 and the substrate 20. A plurality of conductive portions may construct a network portion, and one conductive portion may be referred to as a network of the network portion. In some arrangements, the patterned via layer 330V is within or embedded in the insulating layer 330A. The insulating layer 330A may be referred to as a dielectric layer encapsulating the network portions and bonding the substrate 10 and the substrate 20. The patterned interposer 30 may be referred to as a hybrid bond structure including the network portions and the insulating layer 330A. In some arrangements, the conductive portions 311, 312, 313, 314, 321, 322, 323, and 324 are connected to the patterned via layer 330V. In some arrangements, the conductive portions 311, 312, 313, 314, 321, 322, 323, and 324 electrically connect the substrate 10 to the substrates 20 and 20A. The patterned interposer 30 may be formed from the interposer structure 30A illustrated in FIG. 1.

In some arrangements, the insulating layer 330A contacts the dielectric layer 160. In some arrangements, a rigidity of the insulating layer 330A is less than a rigidity of the dielectric layer 160. In some arrangements, a portion of the insulating layer 330A extends within one or more recesses (e.g., the recesses 1601, 1602, 1603, and 1603) of the dielectric layer 160. In some arrangements, the insulating layer 330A extends over a portion of at least a lateral surface of the substrate 20. In some arrangements, the insulating layer 330A extends over a portion of at least a lateral surface of the substrate 20A. In some arrangements, the insulating layer 330A horizontally overlaps the substrate 10 or the substrate 20. In some arrangements, the insulating layer 330A horizontally overlaps a portion of the network portion (e.g., one or more of the conductive portions 311, 312, 313, 314, 321, 322, 323, and 324). In some arrangements, the insulating layer 330A is made of or includes one or more dielectric materials. In some arrangements, the insulating layer 330A is made of or includes polyimide (PI). The insulating layer 330A may be formed from the patterned dielectric layer 730 of the interposer structure 30A illustrated in FIG. 1.

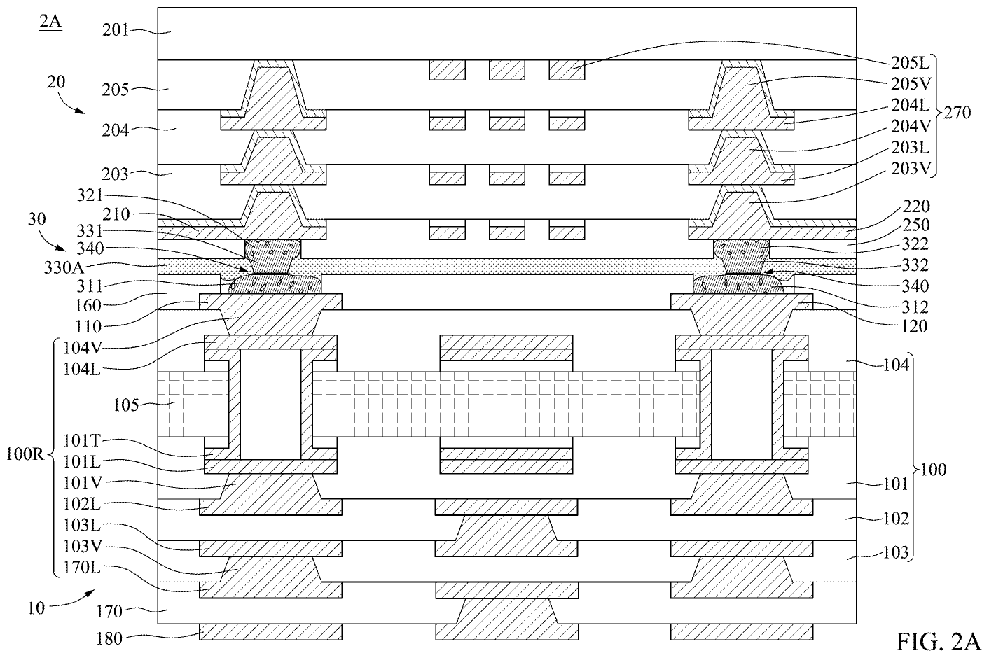

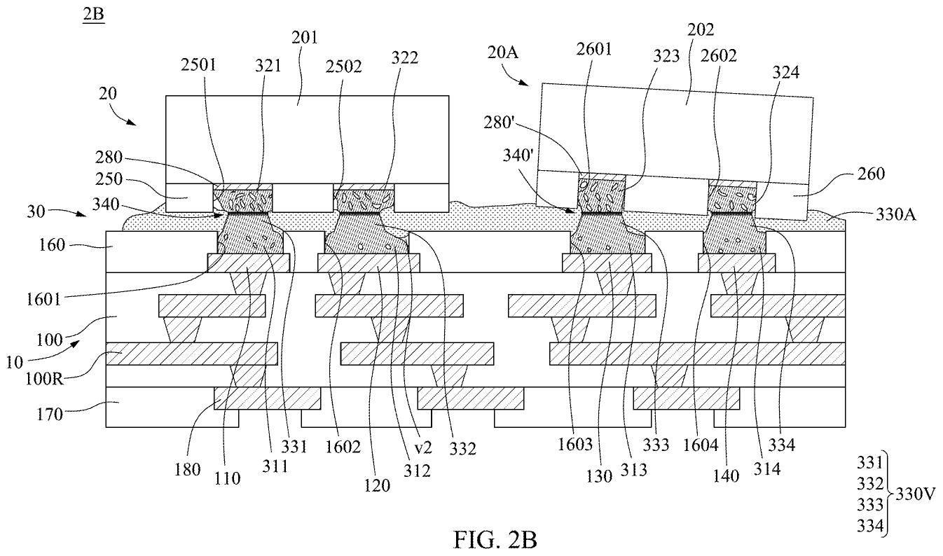

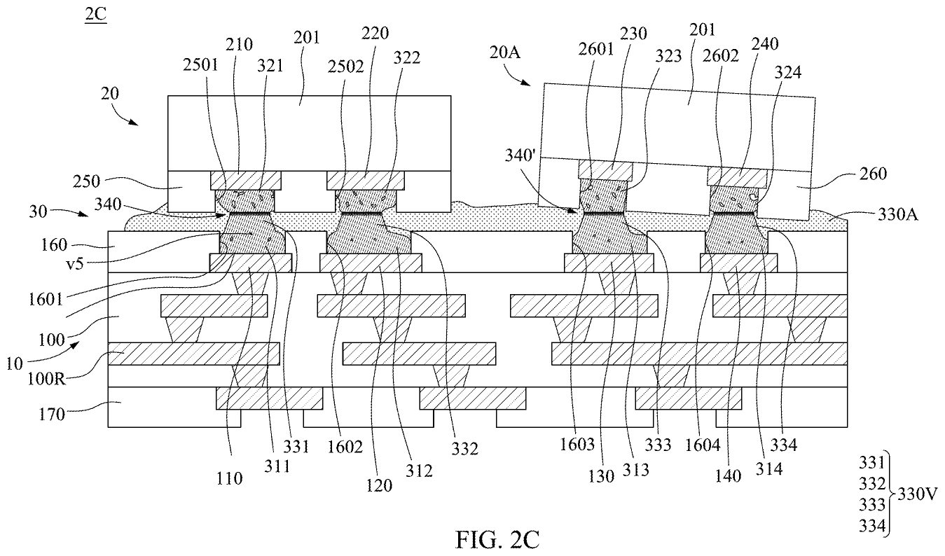

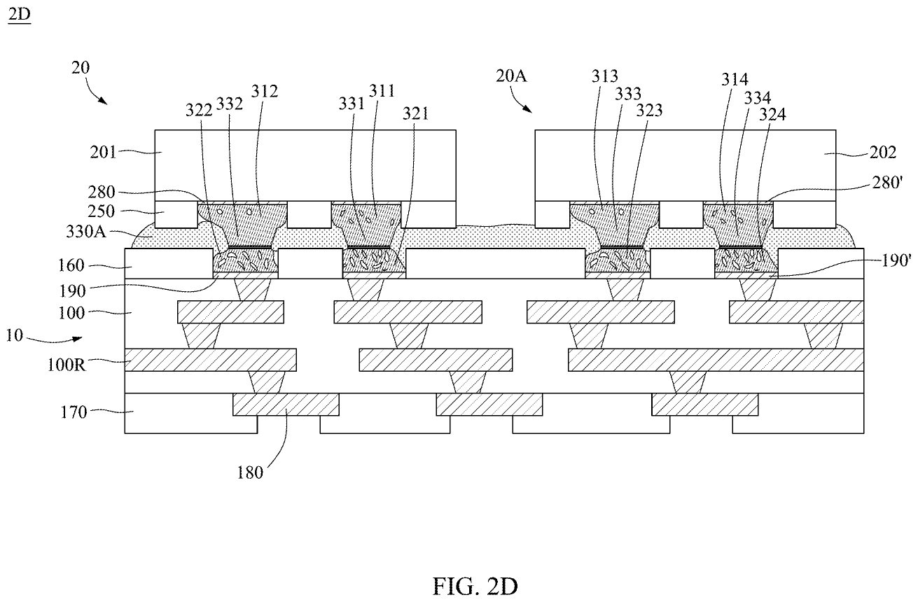

In some arrangements, the patterned via layer 330V includes a plurality of vias (e.g., conductive vias 331, 332, 333, and 334). In some arrangements, the conductive vias 331, 332, 333, and 334 (also referred to as “conductive portions” or “via portions”) are within or embedded in the insulating layer 330A. In some arrangements, the conductive vias 331, 332, 333, and 334 are spaced apart from each other by the insulating layer 330A. The via portions may be interposed by the network portions. For example, the conductive via 331 may be interposed by the network portion formed of the conductive portions 311 and 321. In some arrangements, the conductive vias 331, 332, 333, and 334 are substantially free of voids (e.g., pores, air voids, air gaps, or the like). In some arrangements, the conductive vias 331, 332, 333, and 334 taper toward the substrates 20 and 20A. In some arrangements, the insulating layer 330A and the patterned via layer 330V (e.g., the conductive vias 331, 332, 333, and 334) collectively form a core layer 330 of the patterned interposer 30. In some arrangements, the conductive vias 331, 332, 333, and 334 may be spaced apart from the substrate 10 and/or the substrate 20. In some other arrangements, the conductive vias 331, 332, 333, and 334 may taper away from the substrates 20 and 20A (e.g., referring to the structure illustrated in FIG. 2A).

In some arrangements, the conductive portions 311, 312, 313, and 314 (also referred to as “conductors,” “conductive networks,” “network portions,” or “conductive porous structures”) are connected or electrically connected to the substrate 10. In some arrangements, the conductive portions 311, 312, 313, and 314 (or the networks) are proximal or adjacent to the substrate 10. The conductive network (or the network portion) may be formed from two or more wires (e.g., nanowires) crossing over and connecting to each other. The conductive network (or the network portion) may be formed from two or more wires (e.g., nanowires) interweaving. The conductive porous structure may be formed from a plurality of wires (e.g., nanowires) intersecting and connecting to each other, such that pores or voids may be formed between the intersecting wires. In some arrangements, the conductive portions 311, 312, 313, and 314 connect or electrically connect the patterned via layer 330V to the substrate 10. In some arrangements, the conductive portions 311, 312, 313, and 314 are disposed over, below, out of, or protruded beyond the insulating layer 330A. In some arrangements, the conductive portions 311, 312, 313, and 314 are spaced apart from each other. In some arrangements, at least one of or each of the conductive portions 311, 312, 313, and 314 has more pores (e.g., voids, air voids, air gaps, or the like) than the patterned via layer 330V does. The pores may be formed by performing a bonding operation on wires (e.g., nanowires) that cross over each other, intersect each other, and/or tangle each other. In some arrangements, conductive portion 311 may be formed from the wires 711 of the interposer structure 30A illustrated in FIG. 1, and the pores within the conductive portion 311 may be formed by performing a bonding operation on the wires 711 that cross over each other, intersect each other, and/or tangle each other. In some arrangements, conductive portion 312 may be formed from the wires 712 of the interposer structure 30A illustrated in FIG. 1, and the pores within the conductive portion 312 may be formed by performing a bonding operation on the wires 712 that cross over each other, intersect each other, and/or tangle each other. In some arrangements, the conductive portions 311, 312, 313, and 314 directly extend from the patterned via layer 330V. In some arrangements, each of the conductive portions 311, 312, 313, and 314 directly extends from each of the conductive vias 331, 332, 333, and 334. In some arrangements, a portion of one or more of the conductive portions 311, 312, 313, and 314 extends within one or more recesses (e.g., the recesses 1601, 1602, 1603, and 1604) of the dielectric layer 160. In some arrangements, one or more of the conductive portions 311, 312, 313, and 314 may be at least partially within one or more recesses (e.g., the recesses 1601, 1602, 1603, and 1604) of the dielectric layer 160.

In some arrangements, one or more of the conductive portions 311, 312, 313, and 314 may be connected to or directly contact one or more of the corresponding conductive pads 110, 120, 130, and 140. In some arrangements, one or more voids (e.g., pores, air voids, air gaps, or the like) may be formed between one or more of the conductive portions 311, 312, 313, and 314 and one or more of the corresponding conductive pads 110, 120, 130, and 140. For example, voids v1 may be formed between the conductive portion 311 and the conductive pad 110. In some arrangements, one or more voids (e.g., pores, air voids, air gaps, empty spaced, or the like) may be formed between one or more of the conductive portions 311, 312, 313, and 314 and one or more sidewalls of the recesses (e.g., the recesses 1601, 1602, 1603, and 1604) of the dielectric layer 160. For example, voids v2 may be formed between the conductive portion 312 and a sidewall of the recess 1602. In some arrangements, the pores of the conductive portions 311, 312, 313, and 314 are larger than the pores of the conductive portions 321, 322, 323, and 324.

In some arrangements, the conductive portions 321 and 322 (also referred to as “conductors,” “conductive networks,” or “conductive porous structures”) are connected or electrically connected to the substrate 20. The conductive network (or the network structure) may be formed from two or more wires (e.g., nanowires) crossing over and connecting to each other. The conductive porous structure may be formed from a plurality of wires (e.g., nanowires) intersecting and connecting to each other, such that pores or voids may be formed between the intersecting wires. In some arrangements, the conductive portions 321 and 322 connect or electrically connect the patterned via layer 330V to the substrate 20. In some arrangements, the conductive portions 321 and 322 are disposed over, below, out of, or protruded beyond the insulating layer 330A. In some arrangements, at least one of or each of the conductive portions 321 and 322 has more pores (e.g., voids, air voids, air gaps, or the like) than the patterned via layer 330V does. The pores may be formed by performing a bonding operation on wires (e.g., nanowires) that cross over each other, intersect each other, and/or tangle each other. In some arrangements, conductive portion 321 may be formed from the wires 721A of the interposer structure 30A illustrated in FIG. 1, and the pores within the conductive portion 321 may be formed by performing a bonding operation on the wires 721A that cross over each other, intersect each other, and/or tangle each other. In some arrangements, conductive portion 322 may be formed from the wires 722A of the interposer structure 30A illustrated in FIG. 1, and the pores within the conductive portion 322 may be formed by performing a bonding operation on the wires 722A that cross over each other, intersect each other, and/or tangle each other. In some arrangements, the seed layer structures 340 (or the seed layers) are between the conductive portions 321 and 322 and the patterned via layer 330V. In some arrangements, each of the seed layer structures 340 is between each of the conductive portions 321 and 322 and each of the conductive vias 331 and 332. In some arrangements, a portion of one or more of the conductive portions 321 and 322 extends within one or more recesses (e.g., the recesses 2501 and 2502) of the dielectric layer 250. In some arrangements, one or more of the conductive portions 321 and 322 may be at least partially within one or more recesses (e.g., the recesses 2501 and 2502) of the dielectric layer 250.

In some arrangements, the conductive portions 323 and 324 (also referred to as “conductors,” “conductive networks,” or “conductive porous structures”) are connected or electrically connected to the substrate 20A. In some arrangements, the conductive portions 323 and 324 connect or electrically connect the patterned via layer 330V to the substrate 20A. In some arrangements, the conductive portions 323 and 324 are disposed over, below, out of, or protruded beyond the insulating layer 330A. In some arrangements, at least one of or each of the conductive portions 323 and 324 has more pores (e.g., voids, air voids, air gaps, or the like) than the patterned via layer 330V does. In some arrangements, the seed layer structures 340′ are between the conductive portions 323 and 324 and the patterned via layer 330V. In some arrangements, each of the seed layer structures 340′ is between each of the conductive portions 323 and 324 and each of the conductive vias 333 and 334. In some arrangements, a portion of one or more of the conductive portions 323 and 324 extends within one or more recesses (e.g., the recesses 2601 and 2602) of the dielectric layer 260. In some arrangements, one or more of the conductive portions 323 and 324 may be at least partially within one or more recesses (e.g., the recesses 2601 and 2602) of the dielectric layer 260.

In some arrangements, one or more of the conductive portions 321, 322, 323, and 324 may be connected to or directly contact one or more of the corresponding conductive pads 210, 220, 230, and 240. In some arrangements, one or more voids may be formed between one or more of the conductive portions 321, 322, 323, and 324 and one or more of the corresponding conductive pads 210, 220, 230, and 240. In some arrangements, the conductive portions 321, 322, 323, and 324 are spaced apart from each other. In some arrangements, the conductive portions 321, 322, 323, and 324 (or the networks) are proximal or adjacent to the substrate 20. In some arrangements, a density (or a wire density) of at least one of the conductive portions 321, 322, 323, and 324 is different from a density (or a wire density) of at least one of the conductive portions 311, 312, 313, and 314. In some arrangements, a density (or a wire density) of at least one of the conductive portions 321, 322, 323, and 324 is less than a density (or a wire density) of at least one of the conductive portions 311, 312, 313, and 314.

In some arrangements, at least two or more of the conductive portions 311, 312, 313, 314, 321, 322, 323, and 324 are spaced apart from each other. In some arrangements, at least one or each of the conductive portions 311, 312, 313, 314, 321, 322, 323, and 324 includes a porous structure (e.g., a conductive porous structure). In some arrangements, at least one of or each of the conductive portions 311, 312, 313, 314, 321, 322, 323, and 324 has a conductive network structure (also referred to as “a conductive network”).

In some arrangements, the conductive portions 311 and 321 are connected to the conductive via 331. In some arrangements, the conductive portions 311 and 321 have different numbers of pores (e.g., voids, air voids, air gaps, or the like). In some arrangements, the conductive portion 321 is connected to the substrate 20 and the conductive portion 311. In some arrangements, the conductive via 331 is denser than the conductive portions 311 and 321 (or the conductive networks). In some arrangements, the conductive portions 312 and 322 are connected to the conductive via 332. In some arrangements, the conductive portions 312 and 322 have different numbers of pores. In some arrangements, the conductive portion 322 is connected to the substrate 20 and the conductive portion 312. In some arrangements, the conductive via 332 is denser than the conductive portions 312 and 322 (or the conductive networks). In some arrangements, the conductive portions 313 and 323 are connected to the conductive via 333. In some arrangements, the conductive portions 313 and 323 have different numbers of pores. In some arrangements, the conductive portion 323 is connected to the substrate 20A and the conductive portion 313. In some arrangements, the conductive via 333 is denser than the conductive portions 313 and 323 (or the conductive networks). In some arrangements, the conductive portions 313 and 323 are connected to the conductive via 333. In some arrangements, the conductive portions 314 and 324 have different numbers of pores. In some arrangements, the conductive portion 324 is connected to the substrate 20A and the conductive portion 314. In some arrangements, the conductive via 334 is denser than the conductive portions 314 and 324 (or the conductive networks).

In some arrangements, at least two or more of the conductive portions 311, 312, 313, and 314 have different thicknesses. In some arrangements, at least two or more of the conductive portions 321, 322, 323, and 324 have different thicknesses. For example, a thickness of the conductive portion 321 may be different from a thickness of the conductive portion 323. In some arrangements, the conducive portion 321 includes a porous structure that is recessed within the recess 2501 without protruding beyond a bottom surface of the substrate 20. In some arrangements, the conducive portion 323 includes a porous structure that is protruded beyond a bottom surface of the substrate 20A.

In some arrangements, the seed layer structures 340 and 340′ contact the insulating layer 330A. In some arrangements, each of the seed layer structures 340 and 340′ includes seed layers 341 and 342. In some arrangements, the insulating layer 330A horizontally overlaps the seed layer structures 340 and 340′ (or the seed layers 341 and 342). In some arrangements, the substrate 10 has a top surface 1001 facing the substrate 20, the substrate 20 has a bottom surface 2001 facing the substrate 10, and an elevation of the seed layer structure 340 (or the seed layers 341 and 342) is between an elevation of the top surface 1001 of the substrate 10 and an elevation of the bottom surface 2001 of the substrate 20. The seed layer structures 340 and 340′ may independently include, for example, titanium (Ti), copper (Cu), nickel (Ni), another metal, an alloy (such as a titanium-tungsten alloy (TiW)), or a combination thereof.

In some arrangements, the conductive portion 311 (also referred to as “the lower portion”), the conductive portion 321 (also referred to as “the upper portion”), the conductive via 331 (also referred to as “the via portion”), and the seed layers 341 and 342 may be referred to as a conductive structure electrically connecting the substrate 10 and the substrate 20. In some arrangements, the insulating layer 330A encapsulates the conductive structure. In some arrangements, an elevation of the conductive via 331 (or the via portion) is between an elevation of the top surface 1001 of the substrate 10 and an elevation of the bottom surface 2001 of the substrate 20.

In some arrangements, the dielectric layers may independently include an organic material, a solder mask, PI, an ABF, one or more molding compounds, one or more pre-impregnated composite fibers (e.g., a pre-preg material), borophosphosilicate glass (BPSG), silicon oxide, silicon nitride, silicon oxynitride, undoped silicate glass (USG), any combination thereof, or the like. The conductive layers, pads, and/or vias may independently include a conductive material such as a metal or metal alloy. Examples include gold (Au), silver (Ag), aluminum (Al), copper (Cu), or an alloy thereof.

FIG. 1B is a cross-section of a portion of a package structure in accordance with some arrangements of the present disclosure. In some arrangements, FIG. 1B is a cross-section of a portion 1B of the package structure 1 in FIG. 1A.

In some arrangements, the seed layer structure 340 includes seed layers 341 and 342. In some arrangements, the seed layers 341 and 342 are between the conductive portion 311 (or the conductive network) and the conductive portion 321 (or the conductive network). In some arrangements, the seed layers 341 and 342 are made of or include different materials. In some arrangements, the seed layer 342 and the conductive portions 311 and 312 are made of or include the same material, and the seed layer 341 has a relatively high etching selectivity with respect to the conductive portions 311 and 312. The term “etching selectivity” used hereinafter indicates the ratio of an etching rate of a first material with respect to an etching rate of a second material. In some arrangements, the seed layer 342 and the conductive portions 311 and 312 are made of or include Cu, and the seed layer 341 is made of or includes Ti.

In some arrangements, one or more voids v1 may be formed between the conductive portion 311 and the conductive pad 110. In some arrangements, one or more voids v2 may be formed between the conductive portion 311 and a sidewall of the recess 1601 of the dielectric layer 160. In some arrangements, one or more voids v3 may be formed between the conductive portion 321 and the conductive pad 210. In some arrangements, one or more voids v4 may be formed between the conductive portion 321 and a sidewall of the recess 2501 of the dielectric layer 250. In some arrangements, one or more empty spaces (e.g., the voids v4) may be formed between the insulating layer 330A and a portion of the network portion (e.g., one or more of the conductive portions 311, 312, 313, 314, 321, 322, 323, and 324).

In some arrangements, the conductive portion 311 has voids v5, and the conductive portion 321 has voids v6. In some arrangements, voids v5 are formed within the conductive portion 311, and voids v6 are formed within the conductive portion 321. In some arrangements, one or more of the voids v6 closer to the seed layer structure 340 are larger than one or more of the voids v5 distal from the seed layer structure 340. In some arrangements, a number of the voids v6 is greater than a number of the voids v5. In some arrangements, from a cross-section view, a size of the void v6 is larger than a size of the void v5. In some arrangements, the conductive portion 311 (or the conductive network) is denser than the conductive portion 321 (or the conductive network). In some arrangements, a number or a density of the wires crossing over and intersecting each other to form the conductive portion 311 is greater than a number or a density of the wires crossing over and intersecting each other to form the conductive portion 321. In some arrangements, the dielectric layer 160 defines one or more openings (e.g., recesses 1601, 1602, 1603, and 1604), and the conductive portion 311 extends into the opening and includes a portion that does not contact an inner sidewall of the dielectric layer 160. The conductive portions 312, 313, 314, 322, 323, and 324 may have structures similar to those illustrated in FIG. 1B in accordance with some arrangements of the present disclosure, and the description thereof is omitted hereinafter.

FIG. 1C is a cross-section of a portion of a package structure in accordance with some arrangements of the present disclosure. In some arrangements, FIG. 1C is a cross-section of a portion of the package structure 1 in FIG. 1A. In some arrangements, FIG. 1C is a cross-section of a portion of the structure in FIG. 1B. In some arrangements, FIG. 1C is a cross-section of a portion of the conductive portion 311 (or the conductive network).

In some arrangements, the conductive portion 311 includes a porous structure defining the voids v5. In some arrangements, the conductive portion 311 includes a network structure defining the pores (or the voids v5). In some arrangements, the network structure includes a plurality of wires (or nanowires) crossing and bonding to each other. In some arrangements, the voids v5 within the network structure of the conductive portion 311 have various shapes (e.g., irregular shapes) and various sizes.

In some arrangements, conductive portions 312, 313, 314, 321, 322, 323, and 324 may each have a structure similar to that illustrated in FIG. 1C in accordance with some arrangements of the present disclosure, and the description thereof is omitted hereinafter.

FIG. 1D is a cross-section of a portion of a package structure in accordance with some arrangements of the present disclosure. In some arrangements, FIG. 1D is a cross-section of a portion of the package structure 1 in FIG. 1A. In some arrangements, FIG. 1D is a cross-section of a portion of the structure in FIG. 1B.

In some arrangements, the conductive portion 311 includes a porous structure defining the voids v5. In some arrangements, the conductive portion 311 includes a plurality of wire segments (e.g., segments of nanowires) connected with each other. In some arrangements, the voids v5 may be defined by adjacent bonded wire segments. In some arrangements, the voids v5 within the porous structure of the conductive portion 311 have various shapes (e.g., irregular shapes) and various sizes.

In some cases where dielectric layers (e.g., silicon oxide layers) are used as pre-bonding layers in a hybrid bond structure, in order to provide a sufficient Van der Waals interaction between the dielectric layers, the bonding surfaces of the dielectric layers are required to have relatively low surface roughness (e.g., less than 0.5 nm), and thus CMP operations are required to be performed on the dielectric layers before being bonded to each other. Moreover, dishing of the conductive pads may occur after the CMP operations and may adversely affect the bonding between the conductive pads. Thus, additional attention is required to reduce the dishing of the conductive pads (e.g., less than about 5 nm).

According to some arrangements of the present disclosure, the patterned interposer includes patterned conductive networks formed of wires tangled and connected to each other serving as pre-bonding layers to bond to each other. Therefore, the dielectric layers do not serve as pre-bonding layers and thus do not require to have low surface roughness. Therefore, CMP operations can be omitted, manufacturing operations can be simplified, and the cost can be reduced as well.

In addition, according to some arrangements of the present disclosure, the patterned interposer further includes an insulating layer that may serve as a buffer layer to further compensate the surface roughness of dielectric layers of opposing substrates. Therefore, the dielectric layers do not require to have low surface roughness. Furthermore, the insulating layer has a rigidity smaller than that of the dielectric layer, and thus the insulating layer can further provide buffer to prevent the dielectric layers from being damaged or cracked by hitting each other when bonding to each other upon pressure.

Moreover, according to some arrangements of the present disclosure, the insulating layer may include one or more organic dielectric materials having a Tg lower than about 180° C., and the organic dielectric material may soften and expand upon heating to connect to the dielectric layers of opposing substrates during manufacture. As such, the dielectric layers may have a relatively large surface roughness, particles on the bonding surfaces of the dielectric layers are also allowed, and the softened organic dielectric material may fill in the recesses, concave hoes, and/or cavities resulted from the particles and the relatively large surface roughness of the dielectric layers. Therefore, CMP operations can be omitted, cleaning operations for removing particles from the surfaces of the dielectric layers can also be omitted, and the bonding strength is still not adversely affected at all.

In addition, according to some arrangements of the present disclosure, the softened organic dielectric material of the insulating layer may further fill in spaces between the bonded substrates (e.g., the substrates 10 and 20) during manufacture. As such, the substrates can be bonded to each other to a satisfactory degree without delamination despite that the bonded substrates may tilt with respect to each other or non-parallel to each other. Therefore, the yield can be increased, processing operations can be reduced, and the cost can be reduced as well.

FIG. 2A is a cross-section of a package structure 2A in accordance with some arrangements of the present disclosure. The package structure 2A illustrated in FIG. 2A is similar to that in FIG. 1A, and the differences therebetween are described as follows.

In some arrangements, the substrate 20 is bonded to the substrate 10 through the patterned interposer 30. In some arrangements, the conductive vias 331 and 332 taper toward the substrate 10. In some arrangements, the conductive portions 311 and 312 are connected to or directly contact the conductive pads 110 and 120, respectively. In some arrangements, the conductive portions 321 and 322 are connected to or directly contact the conductive pads 210 and 220, respectively. In some arrangements, the pores of the conductive portions 311 and 312 are larger than the pores of the conductive portions 321 and 322. In some arrangements, a number of the pores of the conductive portions 311 and 312 is greater than a number of the pores of the conductive portions 321 and 322.

In some arrangements, the substrate 10 includes a dielectric structure 100, a wiring structure 100R in the dielectric structure 100, a core layer 105, dielectric layers 160 and 170 over opposite surfaces of the dielectric structure 100, and conductive pads 110 to 120 and 180 respectively over opposite surfaces of the dielectric structure 100. In some arrangements, the wiring structure 100R includes a plurality of wiring layers 101L, 102L, 103L, 104L, and 170L (or conductive layers), a plurality of conductive vias 101V, 103V, and 104V, and a plurality of conductive through vias 101T penetrating the core layer 105. The conductive through via 101T may include a conductive layer on a sidewall of a through hole of the core layer 105 and a dielectric material filled in the through hole surrounded by the conductive layer, and the conductive pad 110 electrically connects to the conductive layer of the conductive through via 101T. In some arrangements, the dielectric structure 100 includes a plurality of dielectric layers 101, 102, and 103 disposed between the wiring layers 101L, 102L, 103L, and 170L. In some arrangements, the dielectric structure 100 further includes at least a dielectric layer 104 disposed between the wiring layer 104L and the conductive pads 110 and 120. In some arrangements, the conductive pads 110 and 120 are disposed on the conductive through vias 101T and connected to the conductive pads 180 through the wiring structure 100R.

In some arrangements, the substrate 20 includes a substrate layer 201, conductive pads 210 and 220, a dielectric layer 250, and a redistribution layer (RDL) 270. In some arrangements, the RDL 270 includes a plurality of conductive layers 203L, 204L, and 205L, a plurality of conductive vias 203V, 204V, and 205V, and a plurality of dielectric layers 203, 204, and 205. One or more of the conductive layers 203L, 204L, and 205L may be or include a conductive pattern including a plurality of conductive pads. One or more of the conductive pads may include seed layer portions and pad portions formed directly on the seed layer portions. The conductive vias 203V, 204V, and 205V may include seed layer portions and via portions formed directly on the seed layer portions.

In some arrangements, the substrate 10 may be referred to as “a lower stacked structure” or a “low-density conductive structure,” and the substrate 20 may be referred to as “a higher stacked structure” or a “high-density conductive structure.” In some arrangements, a line width of the conductive structure (e.g., conductive layers, conductive pads, or the like) of the substrate 10 is greater than a line width of the conductive structure (e.g., conductive layers, conductive pads, or the like) of the substrate 20. In some arrangements, a line spacing of the conductive structure (e.g., conductive layers, conductive pads, or the like) of the substrate 10 is greater than a line spacing of the conductive structure (e.g., conductive layers, conductive pads, or the like) of the substrate 20. In some arrangements, a density of at least one of the conductive portions 321, 322, 323, and 324 is greater than a density of at least one of the conductive portions 311, 312, 313, and 314. In some arrangements, at least one of the voids v6 within at least one of the conductive portions 321, 322, 323, and 324 is smaller than at least one of the voids within at least one of the conductive portions 311, 312, 313, and 314. In some arrangements, the package structure 2A may be referred to as a fan-out substrate (FOSUB) structure.

FIG. 2B is a cross-section of a package structure 2B in accordance with some arrangements of the present disclosure. The package structure 2B illustrated in FIG. 2B is similar to that in FIG. 1A, and the differences therebetween are described as follows.

In some arrangements, the substrate 20 further includes seed layers 280 between the substrate layer 201 and the conductive portions 321 and 322, and the substrate 20A further includes seed layers 280′ between the substrate layer 202 and the conductive portions 323 and 324.

In some arrangements, the conductive portions 321 and 322 may be formed by bonding and annealing wires extending from the seed layers 280 and wires extending from the seed layer structures 340. In some arrangements, there is substantially no void formed between the seed layer 280 and the conductive portion 321. In some arrangements, there is substantially no void formed between the seed layer 280 and the conductive portion 322. In some arrangements, the conductive portions 323 and 324 may be formed by bonding and annealing wires extending from the seed layers 280′ and wires extending from the seed layer structures 340′. In some arrangements, there is substantially no void formed between the seed layer 280′ and the conductive portion 323. In some arrangements, there is substantially no void formed between the seed layer 280′ and the conductive portion 324.

FIG. 2C is a cross-section of a package structure 2C in accordance with some arrangements of the present disclosure. The package structure 2C illustrated in FIG. 2C is similar to that in FIG. 1A, and the differences therebetween are described as follows.

In some arrangements, the conductive portion 311 includes a porous structure and a filling metal portion contacting the porous structure. The filling metal portion is configured to reduce voids (e.g., the voids v5) within the porous structure. The filling metal portion is configured to reduce a number and/or sizes of the voids (e.g., the voids v5) within the porous structure. In some arrangements, the filling metal portion is adjacent to edges of the voids v5. In some arrangements, the porous structure includes a first metal, and the filling metal portion includes a solid solution of the first metal and a second metal different from the first metal. In some arrangements, the first metal may be or include Cu, and the second metal may be or include germanium (Ge), gallium (Ga), silver (Ag), or a combination thereof. In some arrangements, the filling metal portion may include a solid solution CuGe alloy, a solid solution CuGa alloy, a solid solution CuAg alloy, or a combination thereof. In some arrangements, the filling metal portion may be exposed to the voids v5. The filling metal portion may be characterized by EDS.

FIG. 2D is a cross-section of a package structure 2D in accordance with some arrangements of the present disclosure. The package structure 2D illustrated in FIG. 2D is similar to that in FIG. 1A, and the differences therebetween are described as follows.

In some arrangements, the substrates 20 and 20A are substantially parallel to the substrate 10. In some arrangements, the conductive vias 331, 332, 333, and 334 taper toward the substrate 10. In some arrangements, the substrate 10 further includes seed layers 190 between the dielectric structure 100 and the conductive portions 321 and 322 and seed layers 190′ between the dielectric structure 100 and the conductive portions 323 and 324.

In some arrangements, the conductive portions 311 and 312 may be formed by bonding and annealing wires extending from the seed layers 280 and wires extending directly from the conductive vias 331 and 332. In some arrangements, there is substantially no void formed between the seed layer 280 and the conductive portion 311. In some arrangements, there is substantially no void formed between the seed layer 280 and the conductive portion 312. In some arrangements, the conductive portions 313 and 314 may be formed by bonding and annealing wires extending from the seed layers 280′ and wires extending directly from the conductive vias 333 and 333. In some arrangements, there is substantially no void formed between the seed layer 280′ and the conductive portion 313. In some arrangements, there is substantially no void formed between the seed layer 280′ and the conductive portion 314.

In some arrangements, the conductive portions 321 and 322 may be formed by bonding and annealing wires extending from the seed layers 190 and wires extending from the seed layer structures 340. In some arrangements, there is substantially no void formed between the seed layer 190 and the conductive portion 321. In some arrangements, there is substantially no void formed between the seed layer 190 and the conductive portion 322. In some arrangements, the conductive portions 323 and 324 may be formed by bonding and annealing wires extending from the seed layers 190′ and wires extending from the seed layer structures 340′. In some arrangements, there is substantially no void formed between the seed layer 190′ and the conductive portion 323. In some arrangements, there is substantially no void formed between the seed layer 190′ and the conductive portion 324.

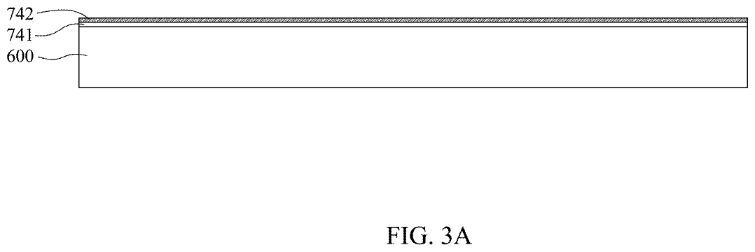

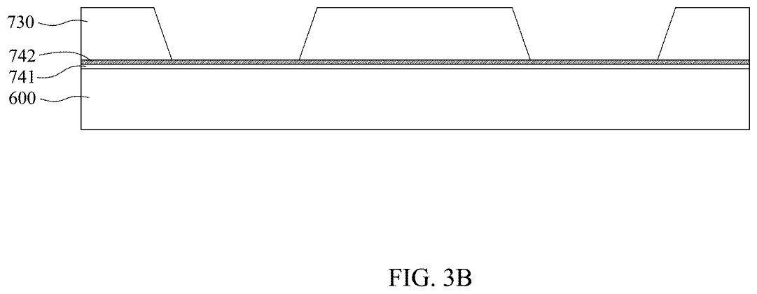

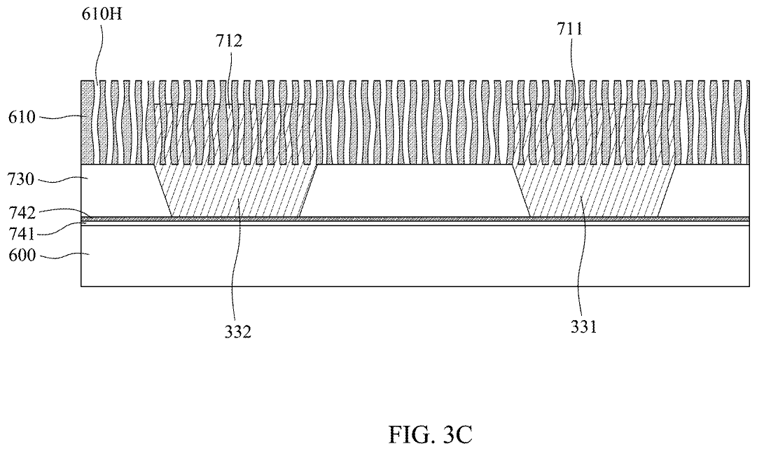

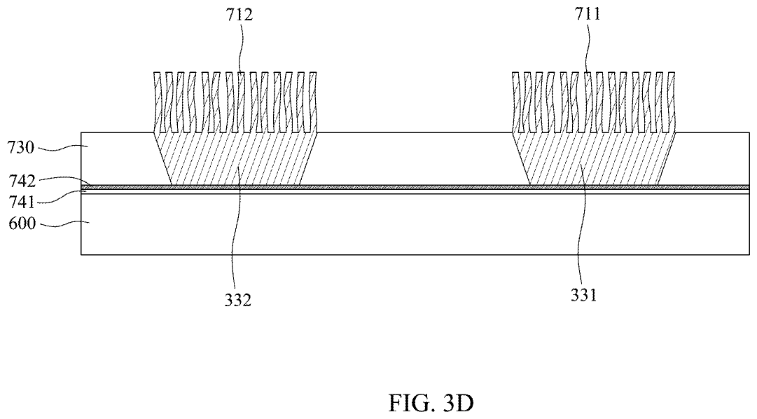

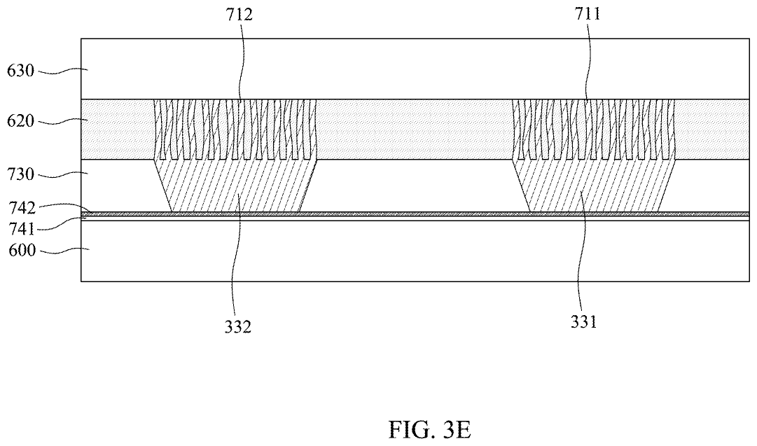

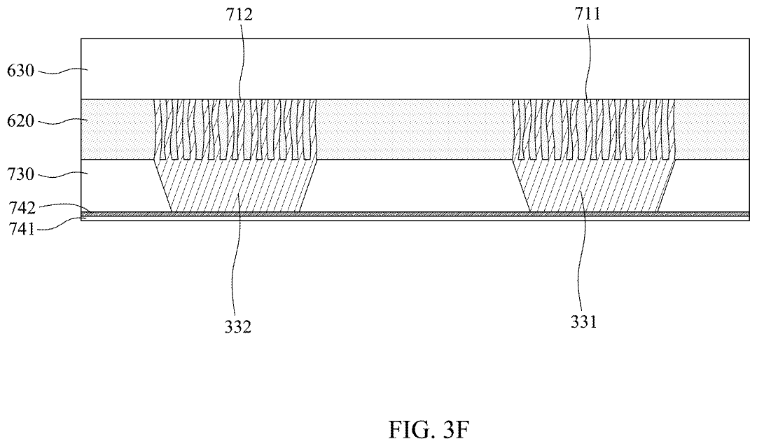

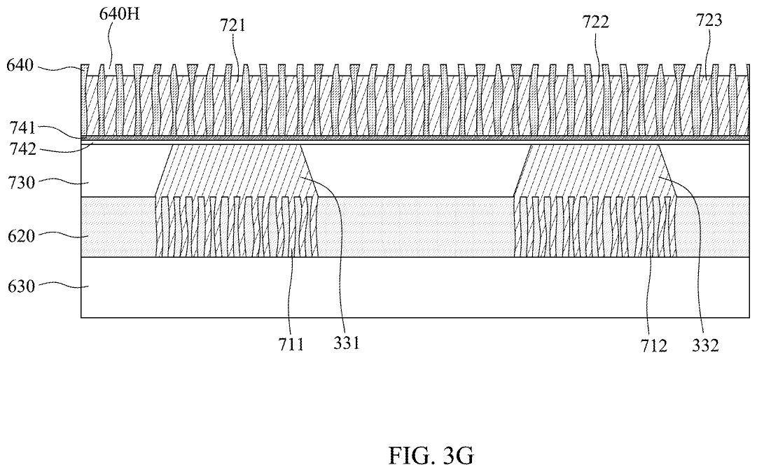

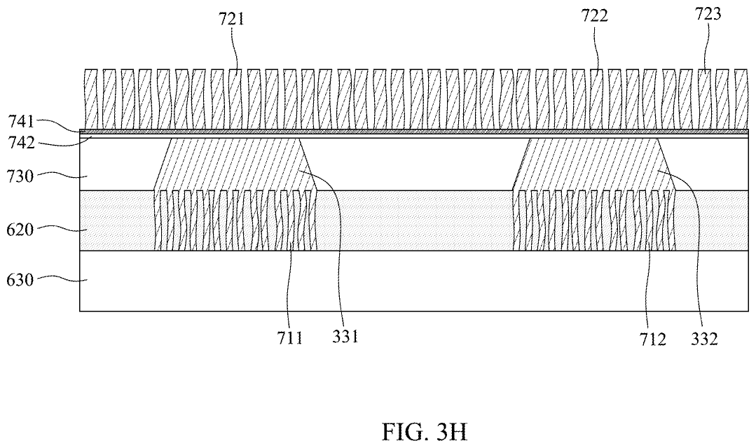

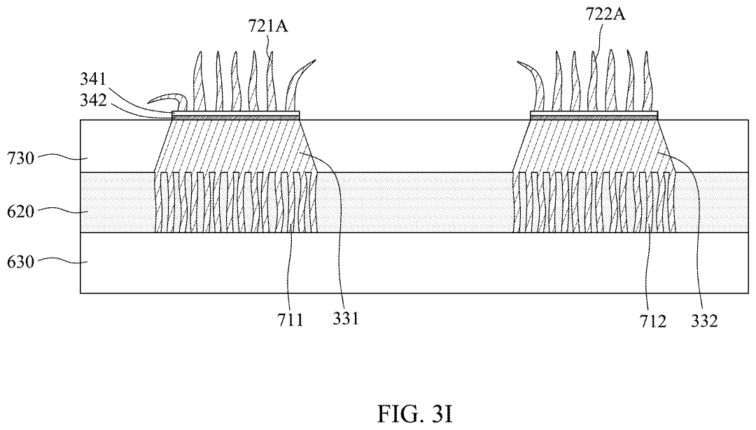

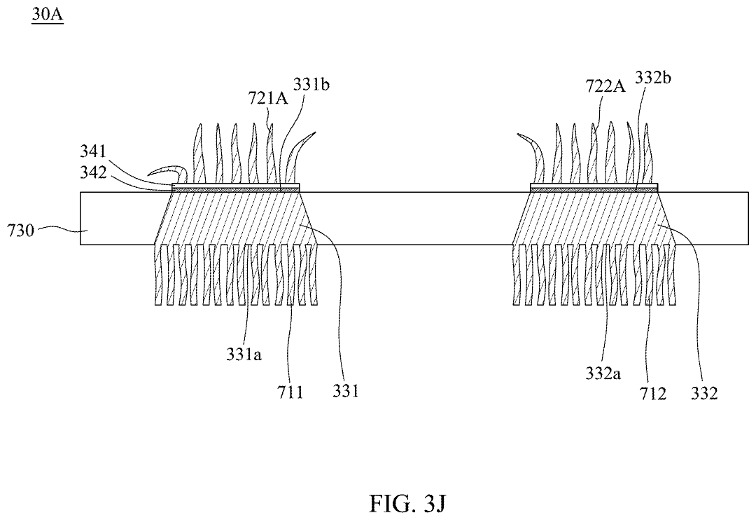

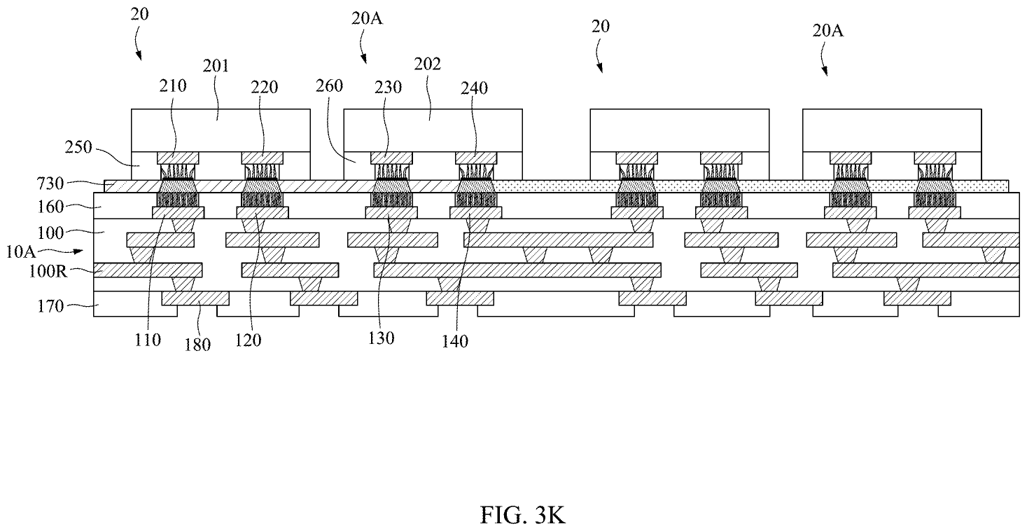

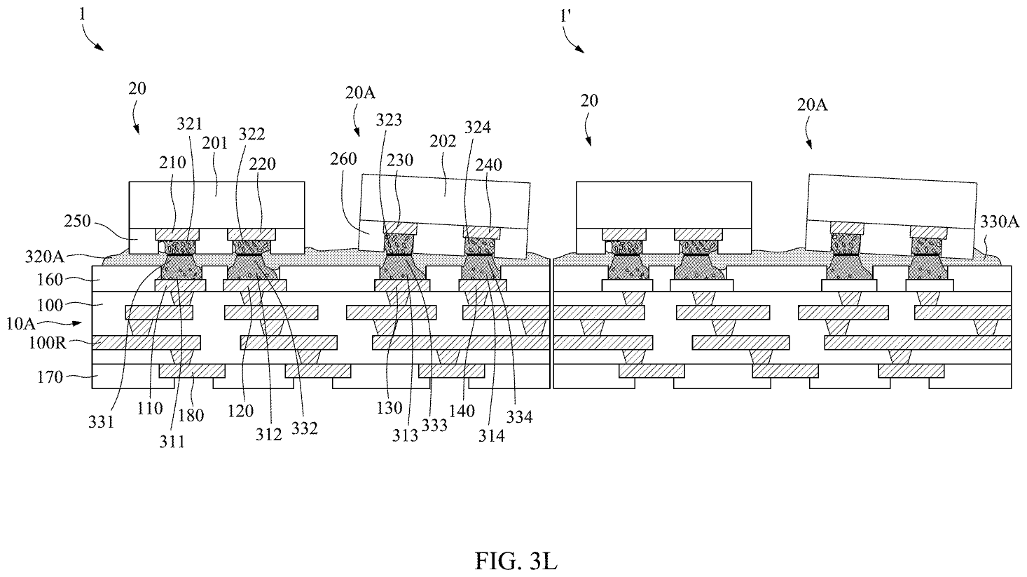

FIG. 3A, FIG. 3B, FIG. 3C, FIG. 3D, FIG. 3E, FIG. 3F, FIG. 3G, FIG. 3H, FIG. 3I, FIG. 3J, FIG. 3K, and FIG. 3L illustrate various stages of an exemplary method for manufacturing a package structure 1 in accordance with some embodiments of the present disclosure.

Referring to FIG. 3A, a carrier 600 may be provided, and conductive layers 741 and 742 may be formed on the carrier 600. In some arrangements, the conductive layers 741 and 742 are made of or include different materials. The some arrangements, the conductive layers 741 and 742 may serve as a seed layer in a following plating process. The conductive layers 741 and 742 may be formed by sputtering.

Referring to FIG. 3B, a patterned dielectric layer 730 may be formed on the conductive layer 742. In some arrangements, the patterned dielectric layer 730 has openings (or recesses) that expose portions of the surface of the conductive layer 742. The patterned dielectric layer 730 may include polyimide (PI).

Referring to FIG. 3C, a template 610 including a plurality of pores 610H may be disposed over the surface of the patterned dielectric layer 730, wires 711 and 712 may be formed in the pores 610H of the template 610, and conductive vias 331 and 332 may be formed in the openings of the patterned dielectric layer 730. In some arrangements, the wires 711 and 712 and the conductive vias 331 and 332 are formed by the same operation. In some arrangements, a plating operation or a deposition operation may be performed to form the wires 711 and 712 and the conductive vias 331 and 332. In some arrangements, the conductive vias 331 and 332 and the wires 711 and 712 are formed continuously in the same plating operation or the same deposition operation.

Referring to FIG. 3D, the template 610 may be removed.

Referring to FIG. 3E, the wires 711 and 712 may be covered by a glue layer 620, and a carrier 630 may be disposed over the glue layer 620. The glue layer 620 may be filled within the wires 711 and 712 and on the exposed surface of the patterned dielectric layer 730. The glue layer 620 may serve as a protective layer for the wires 711 and 712.

Referring to FIG. 3F, the carrier 600 may be removed.

Referring to FIG. 3G, the structure illustrated in FIG. 3F may be flipped over, a template 640 including a plurality of pores 640H may be disposed over the conductive layer 741, and wires 721, 722, and 723 may be formed in the pores 640H of the template 640. In some arrangements, a plating operation or a deposition operation may be performed to form the wires 721, 722, and 723. In some arrangements, a width of the wires 721, 722, and 723 is greater than a width of the wires 711 and 712. In some arrangements, a distribution density of the wires 721, 722, and 723 is lower than a distribution density of the wires 711 and 712.

Referring to FIG. 3H, the template 640 may be removed.

Referring to FIG. 3I, portions of the conductive layers 741 and 742 may be removed to form seed layers 341 and 342, respectively. In some arrangements, the wires 743 over the removed portions of the conductive layers 741 and 742 are removed along with the removal of the portions of the conductive layers 741 and 742. In some arrangements, an etching operation may be performed to remove the portions of the conductive layers 741 and 742 and the wires 723. In some arrangements, the wires 721 and 722 may be partially etched to form wires 721A and 722A having reduced widths and tapered profiles. A distribution density of the wires 721A and 722A is lower than a distribution density of the wires 711 and 712. In some arrangements, a width of the wires 721A and 722A is greater than a width of the wires 711 and 712.

Referring to FIG. 3J, the carrier 630 and the glue layer 620 may be removed. As such, a patterned interposer including a patterned dielectric layer 730 (also referred to as “an insulating buffer layer”), conductive vias (e.g., conductive vias 331 and 332), and conductive wires (e.g., wires 711, 712, 721A, and 722A) may be formed. As such, an interposer structure 30A may be formed.

Referring to FIG. 3K, substrates 10A, 20, and 20A may be provided, and substrates 20 and 20A may be connected or bonded to the substrate 10A by the patterned interposer. The patterned interposer may be disposed or sandwiched between the substrate 10 and the substrates 20 and 20A to bond the substrates 20 and 20A to the substrate 10A. The substrate 10A may include a dielectric structure 100, a wiring structure 100R in the dielectric structure 100, dielectric layers 160 and 170 on opposite surfaces of the dielectric structure 100, and conductive pads (e.g., conductive pads 110, 120, 130, 140, and 180) respectively on opposite surfaces of the dielectric structure 100. Each of the substrates 20 may include a substrate layer 201, a dielectric layer 250 on a bottom surface of the substrate layer 201, and conductive pads 210 and 220 on the bottom surface of the substrate layer 201. Each of the substrates 20A may include a substrate layer 202, a dielectric layer 260 on a bottom surface of the substrate layer 202, and conductive pads 230 and 240 on the bottom surface of the substrate layer 202.

In some arrangements, the wires of the patterned interposer are connected to the conductive pads of the substrates 10A, 20, and 20A. In some arrangements, the wires of the patterned interposer are disposed at least partially within the recesses that expose the conductive pads of the substrates 10A, 20, and 20A. The wires may be connected or bonded to the conductive pads by thermo-compression bonding (TCB). In some arrangements, a sintering operation may be performed on the wires and the conductive pads to bond the wires to the corresponding conductive pads. The sintering operation may be performed under a temperature from about 170° C. to about 200° C. The sintering operation may be performed under a pressure from about 200 MPa to about 230 MPa, e.g., about 215 MPa. The sintering operation may be performed for about 40 seconds to about 2 minutes, e.g., about 1 minute.

In some arrangements, the operation illustrated in FIG. 3I may be omitted, the patterned interposer supported by the carrier 630 may be provided, and substrates 20 and 20A may be bonded to the wires of the patterned interposer supported by the carrier 630. Next, the carrier 630 may be removed, and the wires of the patterned interposer opposite to the substrates 20 and 20A may be bonded to the substrate 10A to form the structure illustrated in FIG. 3K.

Referring to FIG. 3L, an annealing operation may be performed on the sintered wires to form conductive networks (e.g., conductive portions 311, 312, 313, 314, 321, 322, 323, and 324) that connect the conductive pads (e.g., the conductive pads 110, 120, 130, 140, 210, 220, 230, and 240) of the substrates 10A, 20, and 20A to the conductive vias (e.g., the conductive vias 331, 332, 333, and 334) of the patterned interposer. Next, a singulation operation may be performed on the substrate 10A after the annealing operation to form package structures 1 and 1′. The package structure 1′ has a structure similar to that of the package structure 1, except that the insulating layers 330A have different structures. For example, the insulating layer 330A of the package structure 1 has an edge substantially aligned with an edge of the substrate 10 adjacent to the substrate 20A, and the insulating layer 330A of the package structure 1′ has an edge substantially aligned with an edge of the substrate 10 adjacent to the substrate 20.

In some arrangements, the substrate 10 may be connected to the substrate 20 by connecting the conductive pads 110, 120, 130, and 140 to the conductive pads 210, 220, 230, and 240 through the conductive networks (e.g., conductive portions 311, 312, 313, 314, 321, 322, 323, and 324) of the patterned interposer. In some arrangements, the conductive networks having voids or pores may be formed by the annealing operation performed on the wires. In some arrangements, the annealing operation renders the metal atoms (e.g., Cu atoms) of the sintered wires to diffuse and then form the conductive network. In some arrangements, voids formed in a conductive network that is formed by wires having greater widths and/or lower distribution density may be larger than the voids formed in a conductive network that is formed by wires having smaller widths and/or higher distribution density. In some arrangements, a number of voids formed in a conductive network that is formed by wires having greater widths and/or lower distribution density may be greater than a number of the voids formed in a conductive network that is formed by wires having smaller widths and/or higher distribution density. In some arrangements, a number of the voids formed in the conductive portions 321, 322, 323, and 324 is greater than a number of the voids formed in the conductive portions 311, 312, 313, and 314. In some arrangements, the voids formed in the conductive portions 321, 322, 323, and 324 are larger than the voids formed in the conductive portions 311, 312, 313, and 314.

In some other arrangements, a filling metal may be disposed within or at least partially covering the sintered wires before performing the annealing operation. The filling metal may be disposed within the pores of the sintered wires. The filling metal may include Ge, Ga, Ag, Cu, or a combination thereof. Ge and/or Ga having liquid form at room temperature may be disposed within or at least partially covering the sintered wires directly. Ag and/or Cu may be disposed within or at least partially covering the sintered wires by an electroless plating operation. After the filling metal is disposed, voids or pores formed within the conductive network after the annealing operation can be reduced in sizes and numbers. After the annealing operation is performed after disposing the filling metal, a package structure 2C may be formed.

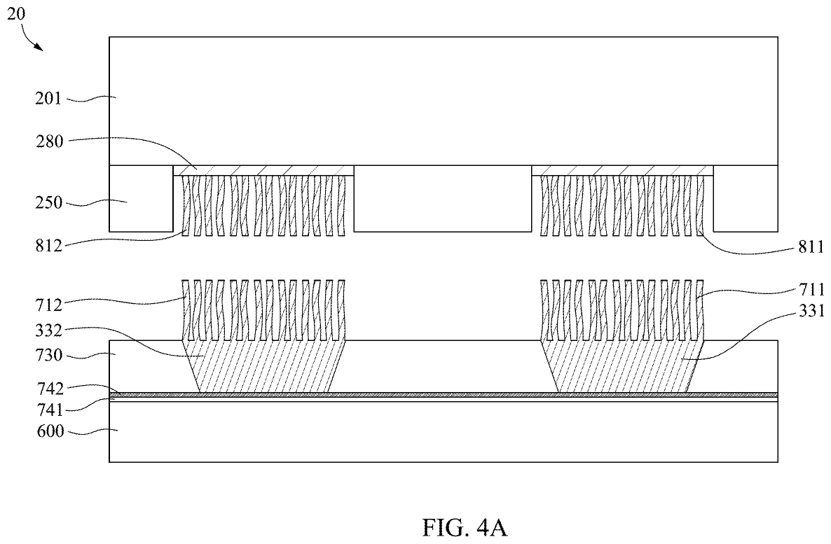

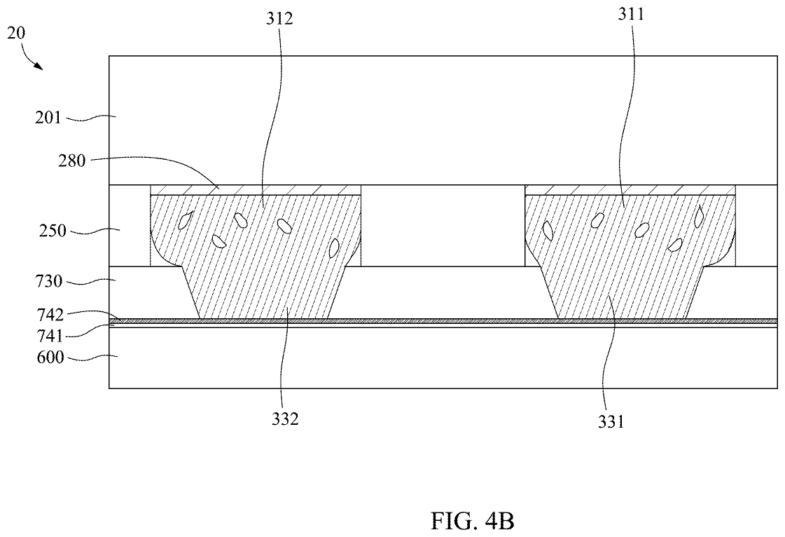

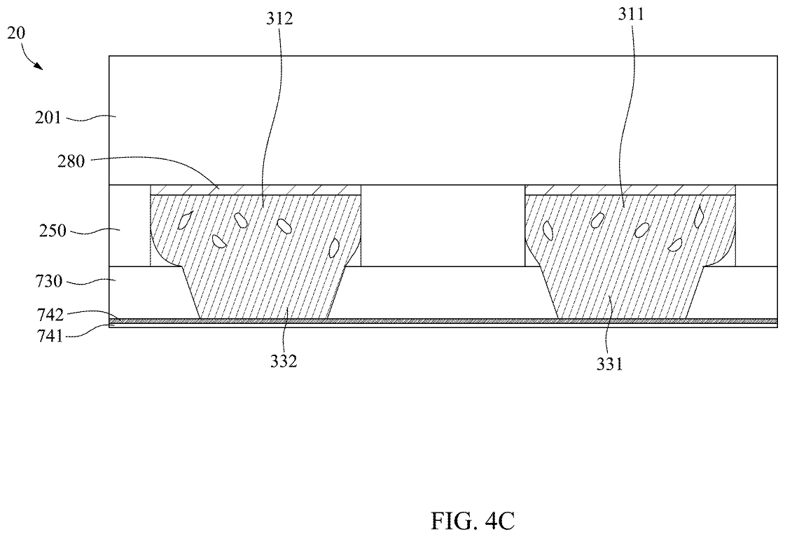

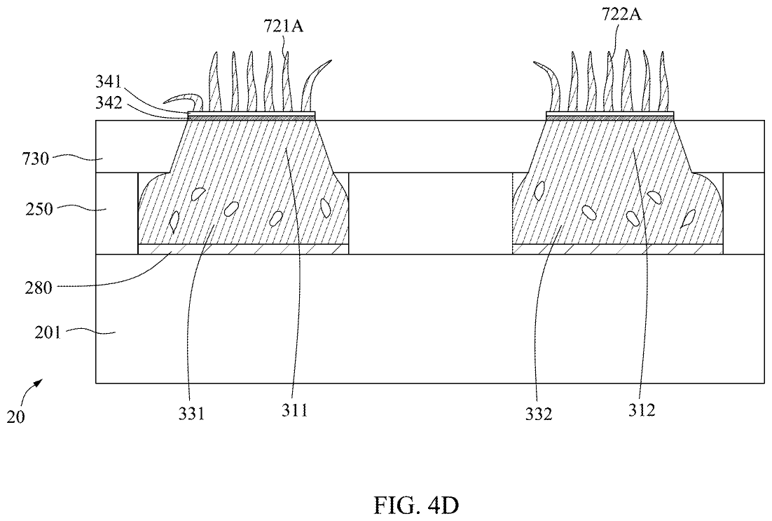

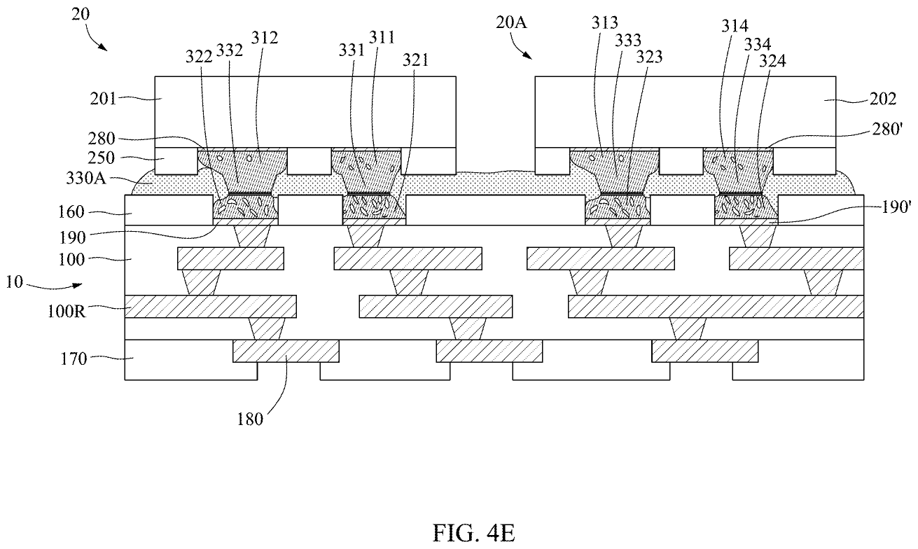

FIG. 4A, FIG. 4B, FIG. 4C, FIG. 4D, and FIG. 4E illustrate various stages of an exemplary method for manufacturing a package structure 2D in accordance with some embodiments of the present disclosure.

Referring to FIG. 4A, operations similar to those illustrated in FIGS. 3A-3D may be performed to form conductive vias (e.g., conductive vias 331 and 332) embedded in the patterned dielectric layer 730 and wires (e.g., wires 711 and 712) extending directly from the conductive vias. A substrate 20 including a substrate layer 201, seed layers 280, a dielectric layer 250, and wires 811 and 812 may be provided, and the wires 811 and 812 may be connected to the wires 711 and 712 by a sintering operation. The sintering operation for bonding wires to wires may be performed under room temperature. In some arrangements, additional conductive vias may be formed within the patterned dielectric layer 730, additional wires may be formed directly on the additional conductive vias, and one or more additional substrates (e.g., the substrate 20A shown in FIG. 4E) may be connected to the additional wires.

Referring to FIG. 4B, operations similar to those illustrated in FIG. 3L may be performed to anneal the connected wires to form conductive networks (e.g., conductive portions 311 and 312).

Referring to FIG. 4C, the carrier 630 may be removed.

Referring to FIG. 4D, operations similar to those illustrated in FIGS. 3G-3I may be performed to form wires (e.g., wires 711A and 712A) on a side of the patterned dielectric layer 730 opposite to the conductive networks connected to the substrate 20.

Referring to FIG. 4E, operations similar to those illustrated in FIGS. 3K and 3L may be performed to connect the wires to the substrate 10. In some arrangements, operations similar to those illustrated in FIGS. 3K and 3L may be performed to connect substrates 20 and 20A to the substrate 10 through the conductive networks on the insulating layer 330A. As such, the package structure 2D may be formed.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of embodiments of this disclosure are not deviated from by such an arrangement.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to +10% of that numerical value, such as less than or equal to +5%, less than or equal to +4%, less than or equal to +3%, less than or equal to +2%, less than or equal to +1%, less than or equal to +0.5%, less than or equal to +0.1%, or less than or equal to +0.05%. For example, a first numerical value can be deemed to be “substantially” the same or equal to a second numerical value if the first numerical value is within a range of variation of less than or equal to #10% of the second numerical value, such as less than or equal to +5%, less than or equal to +4%, less than or equal to +3%, less than or equal to +2%, less than or equal to #1%, less than or equal to +0.5%, less than or equal to +0.1%, or less than or equal to +0.05%. For example, “substantially” perpendicular can refer to a range of angular variation relative to 90° that is less than or equal to +10°, such as less than or equal to +5°, less than or equal to +4°, less than or equal to +3°, less than or equal to +2°, less than or equal to +1°, less than or equal to +0.5°, less than or equal to #0.1°, or less than or equal to +0.05°.

Two surfaces can be deemed to be coplanar or substantially coplanar if a displacement between the two surfaces is no greater than 5 μm, no greater than 2 μm, no greater than 1 μm, or no greater than 0.5 μm. A surface can be deemed to be substantially flat if a displacement between a highest point and a lowest point of the surface is no greater than 5 μm, no greater than 2 μm, no greater than 1 μm, or no greater than 0.5 μm.

As used herein, the singular terms “a,” “an,” and “the” may include plural referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 104 S/m, such as at least 105 S/m or at least 106 S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. An interposer structure, comprising:
a conductive portion having a first surface and a second surface opposite to the first surface;
a dielectric layer encapsulating the conductive portion and exposing the first surface and the second surface;
a plurality of first wires formed on the first surface; and
a plurality of second wires disposed over the second surface.

2. The interposer structure as claimed in claim 1, wherein, in a cross-section view, a pitch of the plurality of first wires is different from a pitch of the plurality of second wires.

3. The interposer structure as claimed in claim 1, further comprising a seed layer between the conductive portion and the plurality of second wires.

4. The interposer structure as claimed in claim 3, wherein, in a cross-section view, the conductive portion tapers toward the seed layer.

5. The interposer structure as claimed in claim 4, wherein a portion of the plurality of first wires is not vertically overlapped by the plurality of second wires.

6. The interposer structure as claimed in claim 4, wherein the conductive portion and the plurality of first wires are continuously formed.

7. A package structure, comprising:
a first substrate;
a second substrate over the first substrate; and
an interposer between the first substrate and the second substrate, the interposer comprising:
a network portion electrically connecting the first substrate and the second substrate; and
a dielectric layer at least partially encapsulating the network portion and bonding the first substrate and the second substrate.

8. The package structure as claimed in claim 7, wherein the interposer further comprises a via portion interposed by the network portion.

9. The package structure as claimed in claim 8, wherein the via portion is spaced apart from the first substrate or the second substrate.

10. The package structure as claimed in claim 7, wherein the dielectric layer horizontally overlaps the network portion.

11. The package structure as claimed in claim 7, wherein the network portion comprises a first network proximal to the first substrate and a second network proximal to the second substrate, and a wire density of the first network is different from a wire density of the second network.

12. The package structure as claimed in claim 11, wherein the second substrate comprises a die, and the wire density of the second network is greater than the wire density of the first network.

13. A package structure, comprising:
a first substrate;
a second substrate over the first substrate; and
an interposer between the first substrate and the second substrate, the interposer comprising a conductive structure electrically connecting the first substrate and the second substrate,
wherein the conductive structure comprises an upper portion, a lower portion, and a seed layer between the upper portion and the lower portion, a first void is formed within the upper portion, and a second void is formed within the lower portion.

14. The package structure as claimed in claim 13, wherein the first substrate has an top surface facing the second substrate, the second substrate has a bottom surface facing the first substrate, and an elevation of the seed layer is between an elevation of the top surface of the first substrate and an elevation of the bottom surface of the second substrate.

15. The package structure as claimed in claim 14, wherein the interposer further comprises a dielectric layer encapsulating the conductive structure, and the dielectric layer horizontally overlaps the seed layer.

16. The package structure as claimed in claim 15, wherein the dielectric layer horizontally overlaps the first substrate or the second substrate.

17. The package structure as claimed in claim 14, wherein the conductive structure further comprises a via portion between the lower portion and the seed layer, and the via portion tapers toward the seed layer.

18. The package structure as claimed in claim 17, wherein the via portion is between the elevation of the top surface of the first substrate and the elevation of the bottom surface of the second substrate.

19. The package structure as claimed in claim 17, wherein from a cross-section view, a size of the first void is larger than a size of the second void.

20. The package structure as claimed in claim 14, wherein the first substrate comprises a first dielectric layer defining a first opening, and the lower portion extends into the first opening, wherein a portion of the lower portion does not contact an inner sidewall of the first opening.
